(19) United States
(12) Patent Application Publication
(10) Pub. No.: US 2007/0096120 A1
(43) Pub. Date: May 3, 2007

(54) Lateral current GaN flip chip LED with shaped transparent substrate

(75) Inventors: Ivan Eliashevich, Maplewood, NJ (US); Hari S. Venugopalan, Somerset, NJ (US); Emil P. Stefanov, Esslingen (DE); Xian-An Cao, Kingston, NY (US); Bryan S. Shelton, Bound Brook, NJ (US)

Correspondence Address: Scott A. McCollister, Esq.;Fay, Sharpe, Fagan, Minnich & McKee, LLP, Seventh Floor, 1100 Superior Avenue, Cleveland, OH, 44114-2579, US

(73) Assignee: GELcore LLC

(21) Appl. No.: 11/260,784

(22) Filed: Oct. 27, 2005

(51) Int. Cl. H01L 31/12

(52) U.S. Cl. 257/82; 257/E33.005

(57) ABSTRACT

An LED device (90) includes: an epitaxial structure (100) having a plurality of layers of semiconductor material and forming an active light-generating region (120) which generates light in response to electrical power being supplied to the LED device (90); and, a substrate (200) that is substantially transparent in a wavelength range corresponding to the light generated by the active light-generating region (120). The substrate has first and second opposing end faces (202, 206) and a plurality of side walls (210) extending therebetween, including a first side wall having a first portion thereof that defines a first surface (212, 214, 216, 218) which is not substantially normal to the first face (202) of the substrate (200). The epitaxial structure (100) is disposed on the first face (202) of the substrate (200).

### BACKGROUND

The present inventive subject matter relates to the lighting arts. It is particularly applicable to high light output green, blue and/or ultraviolet (UV) gallium nitride (GaN) based light emitting diodes (LEDs) and LED arrays, and will be described with particular reference thereto. However, application is also found in connection with other types of LEDs and in other LED applications.

GaN based LEDs, as are commonly known in the art, are suitable for many illumination applications. GaN based LEDs typically emit light in the green, blue and/or UV wavelength ranges. At times, GaN based LEDs employ wavelength-converting phosphors to produce white or other colored light for illumination. Such LEDs have a number of advantages over other types of illuminators, including, e.g., compactness, low operating voltages, and high reliability.

However, GaN based LEDs for lighting applications can suffer from low luminous output. For example, a typical GaN based LED may generate about 100 lumens of light output. In contrast, a typical incandescent light source may generate about 1,000 lumens of light output. One obstacle to high light output in GaN based LEDs is extraction of the light from the device.

With reference to FIG. 1, in a flip chip LED arrangement, an epitaxial structure 10 typically including multiple layers of semiconductor material and forming an active light-generating region 12 (e.g., a double heterostructure, multiple quantum well (MQW), or other suitable light-generating configuration), is usually disposed on a substrate 20 that is substantially transparent or transmissive to light at the wavelength generated. A pair of electrodes and/or electrical contacts 30 (e.g., a p-type and an n-type) are also arranged on the LED in operative electrical communication with the light-generating region 12 so that electrical power supplied to the LED therethrough drives the same to generate light. In a so called lateral current flip chip LED device, the electrodes 30 are commonly located on the same side of the epitaxial structure 10 generally opposite the substrate 20, as opposed to a so called vertical current LED device where the pair of electrodes are usually arranged on two sides of the LED, each on a side opposite from the other.

Commonly, the LED is mounted to a support (e.g., a sub-mount, printed circuit board (PCB), reflector cup, etc.) in flipped orientation, that is, with the light-generating region 12 proximate to the support and the substrate 20 distal from the support. In the flip chip arrangement, the goal is generally to extract a substantial amount of light from the LED through the light-transmissive substrate 20. However, some conventional lateral current flip chip configurations can be disadvantageous in terms of light extraction efficiency.

For example, a refractive index mismatch at an interface 40 between the substrate 20 and epitaxial structure 10 can hinder the light from finding its way into the substrate in the first place, e.g., due to total internal reflection (TIR). Light so trapped is more likely to be absorbed through wave guiding in the epitaxial structure 10 thereby reducing the overall lumens output by the LED. The thickness of the substrate 20 can also contribute to light loss. Additionally, extraction of light from the substrate 20 may also be inhibited by its shape. For example, the side walls 22 of the substrate 20 are typically substantially normal to the opposing end faces of the substrate 20, namely, the end face forming interface 40 with the epitaxial structure 10 and the opposing end face 24. This normal arrangement of the side walls 20 tends to result in light generated by the LED having an angle of incidence therewith that produces TIR, thereby impeding light extraction from the substrate 20.

The present inventive subject matter contemplates a new and improved LED device and/or method for producing and/or using the same that overcomes the above-mentioned limitations and others.

### BRIEF SUMMARY

In accordance with one aspect, an LED device is provided. It includes: an epitaxial structure having a plurality of layers of semiconductor material and forming an active light-generating region which generates light in response to electrical power being supplied to the LED device; and, a substrate that is substantially transparent in a wavelength range corresponding to the light generated by the active light-generating region, the substrate having first and second opposing end faces and a plurality of side walls extending therebetween, including a first side wall having a first portion thereof that defines a first surface which is not substantially normal to the first face of the substrate. The epitaxial structure is disposed on the first face of the substrate.

Numerous advantages and benefits of the present inventive subject matter will become apparent to those of ordinary skill in the art upon reading and understanding the present specification.

### BRIEF DESCRIPTION OF THE DRAWINGS

The present invention may take form in various components and arrangements of components, and in various steps and arrangements of steps. The drawings are only for purposes of illustrating preferred embodiments and are not to be construed as limiting. Further, it is to be appreciated that the drawings are not to scale.

FIG. 1 is a diagrammatic illustration showing a lateral current spread flip chip LED in accordance with a prior art design.

FIG. 2 is a diagrammatic illustration showing an exemplary lateral current spread flip chip LED die or chip with a shaped substrate that embodies aspects of the present inventive subject matter.

FIG. 3 is a diagrammatic illustration showing another exemplary lateral current spread flip chip LED die or chip with a shaped substrate that embodies aspects of the present inventive subject matter.

FIG. 4 is a diagrammatic illustration showing yet another exemplary lateral current spread flip chip LED die or chip with a shaped substrate that embodies aspects of the present inventive subject matter.

FIGS. 5A and 5B are diagrammatic illustrations showing a cross-section view and perspective view, respectively, of an exemplary shaped substrate with recesses for a lateral current spread flip chip LED die or chip that embodies aspects of the present inventive subject matter.

FIG. 6 is a diagrammatic illustration showing the LED die or chip of FIG. 2 arranged in exemplary packaging such that the same embodies aspects of the present inventive subject matter.

FIG. 7 is a diagrammatic illustration showing the LED die or chip of FIG. 3 arranged in exemplary packaging such that the same embodies aspects of the present inventive subject matter.

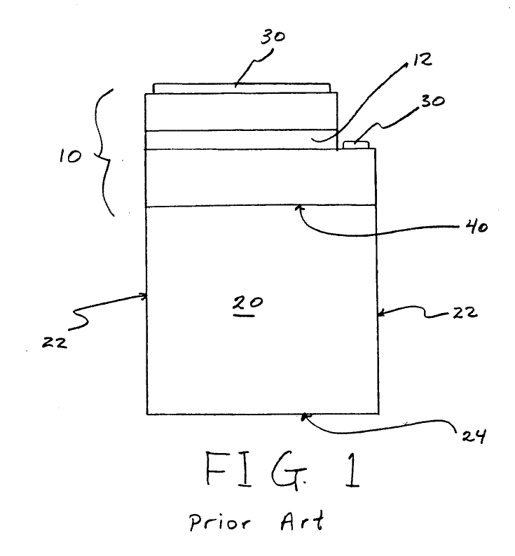

### DETAILED DESCRIPTION OF PREFERRED EMBODIMENTS

With reference to FIGS. 2-4, a lateral current spread flip chip LED die or chip 90 in accordance with suitable embodiments of the present invention includes an epitaxial structure 100 disposed on a shaped substrate 200. The epitaxial structure 100 includes multiple layers of semiconductor material and forms an active light-generating region 120, e.g., a double heterostructure, MQW, or other appropriate light-generating configuration. Suitably, the epitaxial structure 100 comprises a GaN based semiconductor material device that emits light in the green, blue and/or UV wavelength ranges when supplied with electrical power. However, other semiconductor material LEDs are also contemplated.

A pair of electrodes and/or electrical contacts 130 (e.g., a p-type and an n-type) are arranged on the LED chip 90 in operative electrical communication with the light-generating region 120 so that electrical power supplied to the LED chip 90 therethrough drives the same to generate light. Suitably, the devices is a lateral current device and the electrodes 130 are located on the same side of the epitaxial structure 100 opposite the substrate 200.

In a suitable embodiment, preferably the light-generating region 120 is arranged between cladding layers 122, at least one of which is an n-type cladding layer. To achieve an efficient lateral device, the n-type cladding layer is preferably a layer of GaN material having good conductivity, i.e., preferably a conductivity at or below 30 Ohm/sq, and more preferably at or below 20 Ohm/sq. Nevertheless, achieving the desired conductivity can be a challenge with respect to growth. This challenge is, however, preferably overcome by having the layer sufficiently thick (e.g., around 1.5 μm or greater) and/or by using special doping techniques (e.g., delta doping, superlattices (SLs), and/or the like).

The substrate 200 is substantially transparent or transmissive to light of the wavelength generated by the active light-generating region 120 such that at least some portion of the generated light enters the substrate 200 from the epitaxial structure 100, passes through the substrate 200, and is extracted or emitted therefrom through a backside face 206 and/or side walls 210. Suitable materials for the substrate 200 include sapphire (Al₂O₃), silicon carbide (SiC) and gallium nitride (GaN). Optionally, the substrate 200 comprises silicon carbide with an absorption coefficient less than 5.0 cm⁻¹. Alternately, the substrate 200 comprises a nitride material with a refractive index not lower than 2.2 and an absorption coefficient less than 5.0 cm⁻¹. Of course, other suitable transparent substrate materials are also contemplated.

The substrate 200 is suitably a solid mass having a primary thickness t measured as the shortest distance between to two opposing end faces, namely, an epi-side face 202 that forms an interface 204 with the epitaxial structure 100 and the backside face 206 opposite therefrom. Suitably, the end faces are substantially planar and parallel to one another. The end faces optionally have square, rectangular or other polygonal areas that are different in size from one another. As shown in FIG. 2, the epi-side face 202 has an area that is greater than the area of the backside face 206. Alternately, as shown in FIG. 3, the epi-side face 202 has an area that is less than the area of the backside face 206.

A plurality of side walls 210 are disposed and/or extend between the end faces 202 and 206. At least a portion of at least one of the side walls 210 is not substantially normal to the substrate end faces. For example, FIG. 2 shows sides walls 210 having portions that define surfaces 212 (suitably, planar surfaces) that are inclined with respect to the epi-side face 202 to form acute angles therewith. Alternately, FIG. 3 shows sides walls 210 having portions that define surfaces 214 (suitably, planar surfaces) that are inclined with respect to the epi-side face 202 to form obtuse angles therewith. As shown in FIGS. 2 and 3, the shaped substrate 200 substantially takes the form of a truncated pyramid, comparatively in opposite orientations with respect to the epitaxial structure 100.

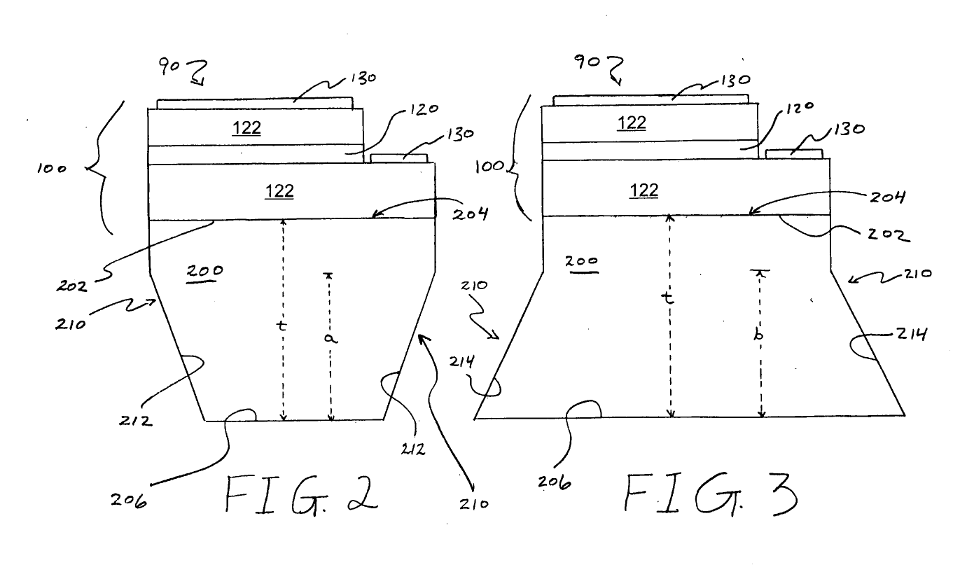

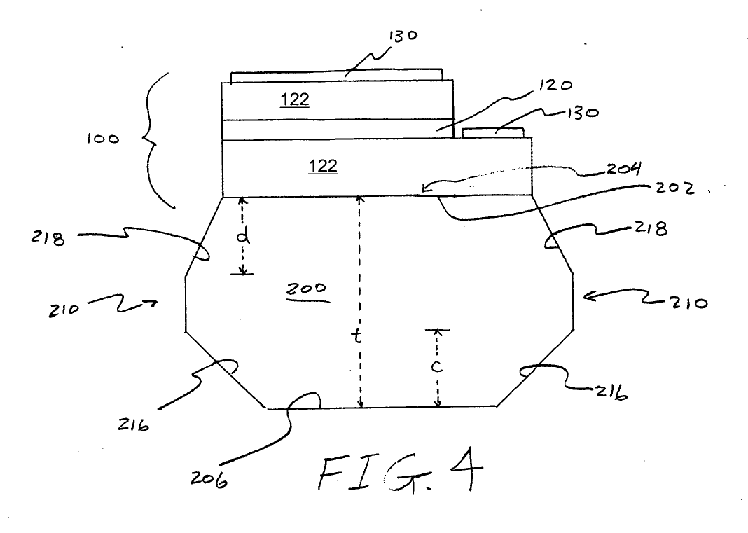

In yet another embodiment shown in FIG. 4, the shaped substrate 200 substantially takes the form of two truncated pyramids combined in opposite orientations with respect to one another. That is to say, the side walls 210 includes portions that define two surfaces which are not substantially normal to the substrate end faces. Specifically, the surfaces 216 (suitably, planar surfaces) are inclined with respect to the epi-side face 202 to form acute angles therewith, and the surfaces 218 (suitably, planar surfaces) are inclined with respect to the epi-side face 202 to form obtuse angles therewith.

Optionally, to achieve a desired light extraction benefit, the substantially non-normal portions of the side walls 210 account for more than 50% of the thickness t. That is to say, with respect to FIG. 2, the distance a is more than 50% of t; with respect to FIG. 3, the distance b is more than 50% of t; and with respect to FIG. 4, the combined distance of c plus d is more than 50% of t. Light extraction from the substrate 200 may be further enhanced by optionally roughening and/or texturing any one or more of the side walls 210 or end faces 202 and 206 so as to inhibit TIR at those surfaces.

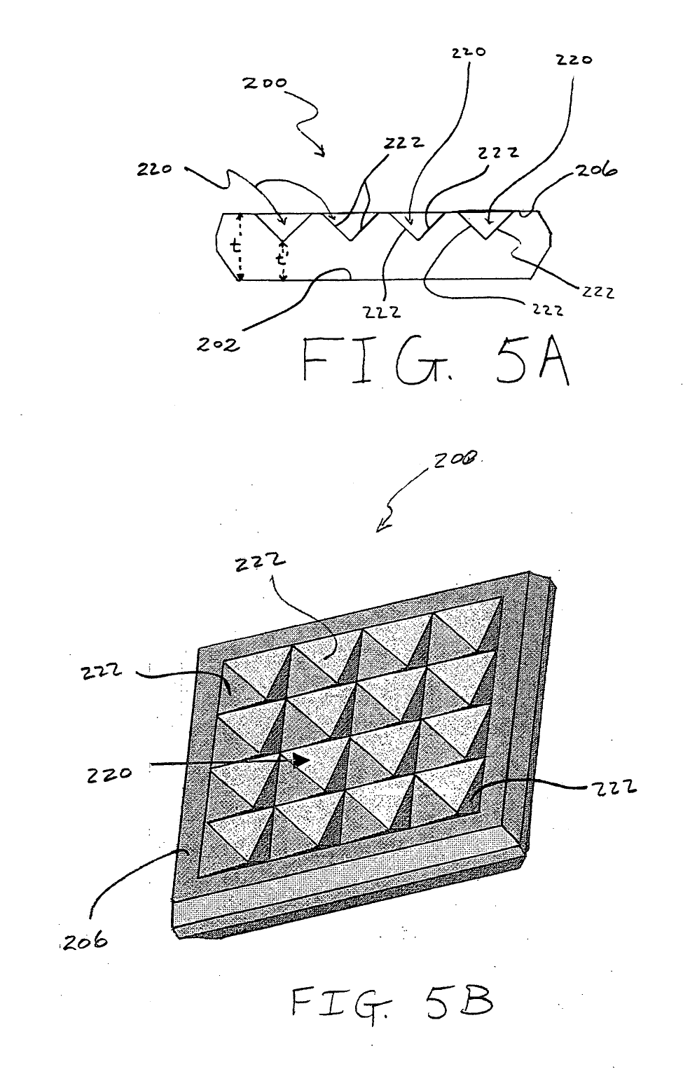

With reference, to FIGS. 5A and 5B, optionally one or more recessed regions are formed in the substrate 200 such that a thickness t′ of the substrate measured in the recessed regions is less than the thickness t measured in the non-recessed regions. Suitably, one or more recesses 220 are formed in the backside face 206 of the substrate 200. While the recesses 220 are shown in conjunction with the side wall configuration of FIG. 4, they are likewise optionally employed with either of the side wall configurations shown in FIGS. 2 and 3. The recesses 220 reduce the effective or mean thickness of the substrate 200 thereby reducing the likelihood of generated light getting absorbed in the substrate 200 insomuch as the effective or mean distance traveled therethrough is reduced. Optionally, the recesses 220 may take any suitable shape or form. However, as shown, the recesses 220 are pyramid shaped. Having the recess walls 222 substantially non-normal or inclined with respect to the backside face 206 further supports light extraction by inhibiting TIR.

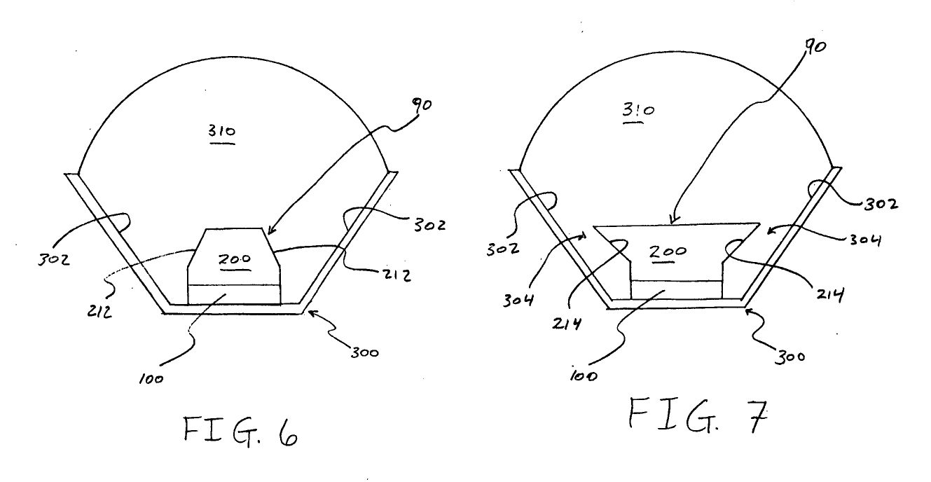

The LED chip 90 is mounted to a support, e.g., a sub-mount, PCB, reflector cup, etc., in flipped orientation, that is, with the light-generating region 120 proximate to the support and the substrate 200 distal from the support. With reference to FIGS. 6 and 7, the LED chip 90 is arranged within a suitable reflector cup 300 so as to reflect the light emitted by the LED chip 90 outward. An appropriate LED encapsulant 310 encapsulates the die or chip 90. Suitably, the encapsulant 310 is substantially transparent or transmissive to light of the wavelength generated and/or emitted by the LED die or chip 90, and it optionally forms a lens for focusing the light passing therethrough. Optionally, the encapsulant 310 is an epoxy with a refractive index higher than 1.5. However, other appropriate encapsulant materials are also contemplated, e.g., various resins or the like. Additionally, phosphors and/or other like wavelength-converting material are optionally employed to convert at least some portion of the light emitted from the LED die 90 from one wavelength to another, e.g., to produce a composite luminous output that appears as white light or some other color light. Suitably, the phosphor is dispersed in the encapsulant 310 and/or coated on the substrate 200.

Optionally, in production, the LED chip 90 is mounted and/or otherwise arranged in the reflector cup 300 prior to being coated with phosphor and/or encapsulated by the encapsulant 310, which is generally poured or otherwise deposited into the reflector cup 300 in an initially liquid or flowing state. Notably, in this case, the embodiment of FIG. 6 has certain advantages. For example, the inclined surfaces 212 of the substrate side walls 210 slope away from, or in the opposite direction of, the inclined surfaces 302 of the reflector cup. Accordingly, there is easy and/or uninhibited access to regions around the LED chip 90 for application of phosphors and/or flowing of the encapsulant 310. Contrastingly, the embodiment of FIG. 7, wherein the inclined surfaces 214 of the substrate side walls 210 slope toward, or in the same direction as, the inclined surfaces 302 of the reflector cup, the gap 304 formed therebetween may restrict flowing of the encapsulant 310 to underlying regions and/or inhibit coating of the same with phosphors.

Also with respect to production, optionally an array of epitaxial structures 100 are deposited on a single substrate wafer that is then diced to form a plurality of individual LED devices 90. Suitably, the dicing is performed with one ore more angled side cuts, e.g., via sawing, laser-cutting or other like separation techniques, to shape the side walls 210. Accordingly, in some instances, e.g., particularly where a high device yield per substrate wafer is desired, the embodiment of FIG. 2 has certain advantages. For example, modeling on otherwise similar devices with square epitaxial structures having a side dimension of 976 μm and substrates in accordance with the embodiments of FIGS. 2 and 3 suggests that the embodiment of FIG. 2 has an increased per wafer chip yield compared to the embodiment of FIG. 3 without substantial expense to the light extraction properties. For achieving effective side wall inclination, a 240 μm street width used in the FIG. 3 embodiment demonstrates a light extraction value of around 38.7% on transparent SiC. A 70 μm street width used in the FIG. 2 embodiment demonstrates a light extraction value of around 35%. However, the larger street width implies a higher loss of active area and a lower number of chips per wafer.

The present inventive subject matter has been described with reference to the preferred embodiments. Obviously, modifications and alterations will occur to others upon reading and understanding the preceding detailed description. It is intended that the invention be construed as including all such modifications and alterations insofar as they come within the scope of the appended claims or the equivalents thereof.

What is claimed is:

1. A light emitting diode (LED) device comprising:
an epitaxial structure including a plurality of layers of semiconductor material and forming an active light-generating region which generates light in response to electrical power being supplied to the LED device; and,
a substrate that is substantially transparent in a wavelength range corresponding to the light generated by the active light-generating region, said substrate having first and second opposing end faces and a plurality of side walls extending therebetween, including a first side wall having a first portion thereof that defines a first surface which is not substantially normal to the first face of the substrate;
wherein said epitaxial structure is disposed on the first face of the substrate.

2. The LED device of claim 1, further comprising:
a pair of electrodes through which electrical power is supplied to the LED, said pair of electrodes being in operative electrical communication with the light-generating region and arranged on a same side of the epitaxial structure opposite the substrate.

3. The LED device of claim 1, wherein the first surface is inclined with respect to the first face to form an acute angle therewith.

4. The LED device of claim 1, wherein the first surface is inclined with respect to the first face to form an obtuse angle therewith.

5. The LED device of claim 1, wherein at least one of the end faces and side walls has a substantially roughened surface.

6. The LED device of claim 1, wherein the first and second end faces of the substrate have areas that are different from one another.

7. The LED device of claim 6, where the area of the first end face is greater than the area of the second end face.

8. The LED device of claim 6, where the area of the first end face is less than the area of the second end face.

9. The LED device of claim 1, wherein the substrate comprises a material selected from the group consisting of sapphire, silicon carbide and gallium nitride.

10. The LED device of claim 1, wherein the substrate comprises silicon carbide with an absorption coefficient less than 5.0 cm⁻¹.

11. The LED device of claim 1, wherein the substrate comprises a nitride with a refractive index not lower than 2.2 and an absorption coefficient less than 5.0 cm⁻¹.

12. The LED device of claim 1, further comprising:
a substantially transparent encapsulant at least partially encapsulating the epitaxial structure and substrate.

13. The LED device of claim 1, wherein the encapsulant is an epoxy with a refractive index higher than 1.5.

14. The LED device of claim 1, wherein the second face of the substrate has one or more recessed regions formed therein such that a thickness of the substrate measured between the first face and the second face is less in the recessed regions than in the non-recessed regions.

15. The LED device of claim 1, wherein the first side wall has a second portion thereof different from the first portion that defines a second surface which is also not substantially normal to the first face of the substrate.

16. The LED device of claim 15, wherein the first surface is inclined with respect to the first face to form an acute angle therewith and the second surface is inclined with respect to the first face to form an obtuse angle therewith.

17. The LED device of claim 1, wherein the substrate has a thickness defined between the first and second end faces and the first portion of the first side wall accounts for more than 50% of that thickness.

18. The LED device of claim 1, wherein a wavelength of the light generated by the active light-generating region is in a range selected from green, blue or ultraviolet.

19. The LED device of claim 1, wherein the epitaxial structure is a gallium nitride based semiconductor device.
